(19) United States
(12) Patent Application Publication
(10) Pub. No.: US 2005/0136610 A1
(43) Pub. Date: Jun. 23, 2005

(54) Process for forming oxide film, apparatus for forming oxide film and material for electronic device

(75) Inventors: Junichi Kitagawa, Amagasaki-shi (JP); Shinji Ide, Amagasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/036,128

(22) Filed: Jan. 18, 2005

Related U.S. Application Data
(63) Continuation-in-part of application No. PCT/JP03/09111, filed on Jul. 17, 2003.

(30) Foreign Application Priority Data
Jul. 17, 2002 (JP) 2002-208803

(51) Int. Cl. H01L 29/76; H01L 29/94; H01L 31/062; H01L 31/113; H01L 31/119; H01L 21/76

(52) U.S. Cl. 438/402; 257/288

(57) ABSTRACT

In the presence of a process gas comprising at least an oxygen gas and a hydrogen gas, the surface of a substrate for electronic device is irradiated with plasma based on oxygen and hydrogen, to thereby form an oxide film on the substrate for electronic device. There is provided a process for forming an oxide film and an apparatus for forming oxide film which can provide a high-quality oxide film and can easily control the thickness of the oxide film, and a material for electronic device having such a high-quality oxide film.

This application is a continuation-in-part application of International Application No. PCT/JP03/09111, filed on Jul. 17, 2003.

### TECHNICAL FIELD

The present invention-relates to a process for forming an oxide film, which is capable of suitably forming an oxide film as one of the key technologies for electronic device fabrication, an apparatus for forming oxide film wherein the formation process may suitably be used, and a material for electronic device which may suitably be fabricated by using the formation process or formation apparatus. The process for producing an oxide film according to the present invention may suitably be used, for example, for forming a material to be used for a semiconductor or semiconductor device (for example, those having an MOS-type semiconductor structure, thin-film transistor (TFT) structure, etc.).

### BACKGROUND ART

In general, the present invention is widely applicable to the production of materials for electronic device such as semiconductors or semiconductor devices, and liquid crystal devices. For the convenience of explanation, however, the background art relating to semiconductor devices as an example of the electronic devices, will be described here.

Along with the requirement for the fabrication of finer patterns in semiconductor devices in recent years, there has remarkably been increased the demand for a high-quality insulating film or oxide film such as silicon oxide film (SiO₂ film), the thickness of which may be easily controlled to a desired value. For example, with respect to an MOS-type semiconductor structure, as the most popular semiconductor device structure, in accordance with the so-called scaling rule, the demand for an extremely thin (e.g., the thickness on-the order of 2.5 nm or less) and high-quality gate insulator (SiO₂ film) becomes extremely high.

Heretofore, for the purpose of such an oxide film, a thermal oxidation method has been used. In this method, however, it is difficult to control the thickness of the thermal oxidation film to those corresponding to a thin film.

Therefore, in this method, the thin film formation have been practiced by using a lower temperature and a lower pressure. Even in such a method, however, a high temperature (800° C. or more) is essentially required. On the other hand, for example, as a technique for forming a high-quality oxide film, an oxidation technique using plasma at a low temperature (about 400 ° C.) has heretofore been investigated. However, the process for forming an oxide film using the plasma treatment has a problem such that the rate of the formation thereof is very low.

In the above-mentioned thermal oxidation method, it is ordinarily required to heat the interior of the thermal oxidation chamber to a high temperature of 800-1000° C., in order to increase the rate of the silicon oxide film formation to a practically acceptable level thereof. Accordingly, the conventional thermal oxidation method may cause a phenomenon such that the respective portions of the resultant integrated circuit are thermally damaged, or various dopants in the semiconductor material are undesirably diffused. As a result, the quality of the final semiconductor devices obtained by such a method can be deteriorated.

In addition, in recent years, in view of an improvement in the productivity, it has been strongly demanded to use a so-called large-diameter (300 mm) substrate for electronic devices (wafer). In the case of the large-diameter wafer, it is extremely difficult to uniformly heat or cool the wafer, as compared in the case of a conventional diameter (200 mm) wafer, and accordingly, it is difficult to treat the large-diameter wafer by using the conventional thermal oxidation method.

### DISCLOSURE OF INVENTION

An object of the present invention is to provide a process for forming an oxide film and an apparatus for forming oxide film which can solve the above-mentioned problem encountered in the prior art, and a material for electronic device having a high-quality oxide film.

Another object of the present invention is to provide a process for forming an oxide film and an apparatus for forming oxide film which can provide a high-quality oxide film and can easily control the thickness of the oxide film, and a material for electronic device having such a high-quality oxide film.

A further object of the present invention is to provide a process for forming an oxide film and an apparatus for forming oxide film which can process an object to be processed while suppressing the thermal damage thereto as little as possible, and a material for electronic device having such a high-quality oxide film.

As a result of earnest study, the present inventors have found that it is extremely effective in achieving the above object to use an oxygen gas in combination with plasma and a hydrogen gas (instead of using an oxygen gas alone as in the prior art) so as to rather enhance the rate of the oxidation on a silicon substrate.

The process for forming an oxide film according to the present invention is based on the above discovery. More specifically, the present invention provides a process for forming an oxide film, wherein in the presence of a process gas comprising at least an oxygen gas and a hydrogen gas, the surface of a substrate for electronic device is irradiated with plasma based on oxygen and hydrogen, to thereby form an oxide film on the substrate for electronic device.

The present invention also provides a material for electronic device, comprising: a substrate for electronic device; and an oxide film covering at least a portion of a surface of the electronic device substrate; wherein the ratio (Rp/Rs) between the surface roughness (Rs) of the electronic device substrate before the formation of the oxide film, and the surface roughness (Rp) of the oxide film which has been formed on the electronic device substrate is 2 or less.

According to the process for forming an oxide film according to the present invention having the above constitution, it is possible to obtain a high-quality oxide film at a good oxide film formation-rate. It is possible to confirm the high quality of the oxide film, e.g. by the bonding state in the oxide film and the surface roughness of the oxide film. According to the present inventors' investigation and knowledge, it is presumed that, on the generation of the plasma and using hydrogen gas and oxygen gas, H atoms are diffused in advance into the interior of the electronic device substrate (or base material) so that the unstable Si—O bonds are removed or reduced, and the Si—O bonds are converted into stable bonds by active O atoms, whereby the high-quality oxide film can be formed.

Further, in the present invention, it is possible to easily control the film thickness of the oxide film to be formed, because the oxide film can be formed at an appropriate (not too high) rate, as compared with that in the conventional field (or thermal) oxidation method.

In addition, an oxide film can be formed at a relatively high rate by using plasma having a low electron temperature at a low temperature so as to consequently reduce the damage to an object to be processed, whereby it is possible to further enhance the quality of the oxide film easily.

### BRIEF DESCRIPTION OF DRAWINGS

FIG. 1 is a schematic plan view showing an example of the semiconductor manufacturing equipment for conducting a process for forming an oxide film according to the present invention.

FIG. 2 is a schematic vertical sectional view showing an example of the plasma processing unit comprising a slot plane (or planar) antenna, which is usable in the process for forming an oxide film according to the present invention.

FIG. 3 is a schematic plan view showing an example of the SPA which is usable in the process for forming an oxide film according to the present invention.

FIG. 4 is a schematic vertical sectional view showing an example of the plasma processing unit which is usable for the process for forming an electronic device material according to the present invention.

FIG. 5 is a graph showing the rate of oxide film formation provided by a process for forming an oxide film according to the present invention.

FIG. 6 is a graph showing an etching characteristic of the oxide film provided by a process for forming an oxide film according to the present invention.

FIG. 7 is a graph showing interfacial level (or state) density of the oxide film provided by a process for forming an oxide film according to the present invention.

FIG. 8 is a graph showing chemical composition measurement by XPS on the oxide film provided by a process for forming an oxide film according to the present invention in.

FIG. 9 is a graph showing the results of the surface roughness measurement by AFM of the oxide film provided by a process for forming an oxide film according to the present invention.

FIG. 10 is a graph showing the results (data obtained in Example 7) of the refractive index and relative density measurement on the oxide film (the oxide film provided by the addition of hydrogen) obtained in Example 1, and on the conventional oxide film.

FIG. 11 show data (obtained in Example 8) illustrating the results of the density measurement using an X-ray reflection method as a verification of the data of Example 7.

FIG. 12 is a graph showing the electric properties of the MOS semiconductor structure provided in Example 9.

In the above-mentioned figures, the respective reference numerals have the following meanings:
W: wafer (substrate to be processed
60: slot plane antenna (plane antenna member)
2: oxide film
2a: nitrogen-containing layer
32: plasma-processing unit (process chamber)
33: plasma-processing unit (process chamber)
47: heating reaction furnace.

### BEST MODE FOR CARRYING OUT THE INVENTION

Hereinbelow, the present invention will be described in detail with reference to the accompanying drawings as desired. In the following description, “%” and “part(s)” representing a quantitative proportion or ratio are those based on mass, unless otherwise noted specifically.

(Formation of the Oxide Film)

In the present invention, in the presence of a process gas comprising at least oxygen and hydrogen, the surface of a substrate for electronic device is irradiated with plasma based on oxygen and hydrogen, to thereby form an oxide film on the surface of the electronic device substrate.

(Electronic Device Substrate)

The electronic device substrate which is usable in the present invention is not particularly limited, and one or a combination of two or more appropriately selected from known electronic device substrates can be used. Examples of the electronic device substrate may include semiconductor materials and liquid crystal device materials. Examples of the semiconductor material may include a material-mainly comprising single crystal silicon, polysilicon, nitrided silicon, etc.

(Oxide Film)

In the present invention, the oxide film to be disposed on the substrate for electronic device is not particularly limited, as long as such an oxide film can be formed by oxidizing the substrate for electronic device. The oxide film may include one kind or a combination two kinds or more of known oxide films for electronic devices. Examples of the oxide film may include silicon oxide film (SiO₂), etc.

(Process Gas)

In the present invention, at the time of forming an oxide film, the process gas may comprise at least oxygen, hydrogen and an inert gas. The inert gas usable in this case is not particularly limited, but it is possible to use a gas (or a combination of two or more kinds of gases) which is appropriately selected from known inert gases. In view of the cost performance, it is preferred to use an inert gas such as argon, helium or krypton.

(Conditions for Oxide Film Formation)

In an embodiment wherein the present invention is applied for the formation of an oxide film, in view of the characteristic of the oxide film to be formed, the following conditions may suitably be used:
O₂: 1-10 sccm, more preferably 1-5 sccm,
H₂: 1-10 sccm, more preferably 1-5 sccm,
Inert gas (for example, Kr, Ar or He): 100-1000 sccm, more preferably 100-500 sccm,
Temperature: room temperature (25° C.) to 500° C., more preferably room temperature to 400° C.,
Pressure: 66.7-266.6 Pa, more preferably 66.7-133.3 Pa,
Microwave: 3-4 W/cm², more preferably 3-3.5 W/cm2
   (Examples of Suitable Conditions)

In the present invention, in view of a further improvement in the effect thereof, the following conditions may be raised as examples of the particularly preferred conditions:
Flow rate ratio of H₂/O₂ gas: 2:1 to 1:2, more preferably about 1:1
Flow rate ratio of H₂/O₂/inert gas: 0.5:0.5:100 to 2:2:100
Temperature: 500° C. or below, more preferably 400° C. or below.

In the case of the formation of a device element on a semiconductor substrate, it is general that an impurity is preliminarily diffused in the substrate so as to form an active, and an element-isolation region. However, in the conventional thermal oxidation technique, the high temperature to be used therefor can problematically break the impurity-containing region.

On the other hand, in the present invention, a low temperature treatment can protect the impurity-containing region, and further, can suppress the thermal damage by heat and strain, etc.

In addition, a desired film (e.g., a CVD film) may preferably be formed at a relatively low temperature (about 500° C.) on an oxide film which has been formed according to the present invention, and the resultant film is suitable for the subsequent oxidation process. In this case, the process management therefor becomes easy.

(Electronic Device Material Having Oxide Film)

The present invention may preferably provide an electronic device material comprising a silicon substrate and an oxide film disposed thereon. In this electronic device material, the ratio (Rp/Rs) between the surface roughness (Rs) of the electronic device substrate before the formation of the oxide film, and the surface roughness (Rp) of the oxide film which had been formed on the electronic device substrate may preferably be 2 or less. The Rp/Rs ratio may more preferably be 1.0 or less.

For example, the surface roughness Rs and Rp may preferably be measured under the following conditions.

<Conditions for Surface Roughness Measurement>

The surface roughness of the order of 0.1 nm may be determined by measuring a surface region of about 1 μm×1 μm by use of an atomic force microscope (AFM).

(Density of Oxide Film)

The present invention can easily provide an oxide film having a higher density than that of the conventional thermal oxide film.

For example, when the above-mentioned substrate for electronic device is a silicon substrate, the present invention can easily provide an oxide film having a density of about 2.3. On the other hand, the conventional thermal oxide film ordinarily has a density of about 2.2.

The density of this oxide film may preferably measured under the following conditions.

<Conditions for Oxide Film Density Measurement>

(1) The refractive index of the oxide film is measured by an ellipsometry method. In the case of SiO₂, the density thereof is substantially proportional to the refractive index thereof. Therefore, the density can be determined from the refractive index.

(2) The density of a film having-a known composition can be determined by an X-ray Reflectivity technique (particularly, Grazing Incidence X-ray Reflectivity technique (GIXR)).

(Apparatus for Forming Oxide Film)

The apparatus for forming an oxide film according to the present invention comprises: at least, a reaction container for disposing a substrate for electronic device at a predetermined position therein; gas supply means for supplying oxygen and hydrogen into the reaction container; and plasma excitation means for plasma-exciting the oxygen and hydrogen, whereby the surface of the electronic device substrate can be irradiated with the plasma based on the oxygen and hydrogen. In the present invention, the above plasma excitation means is not particularly limited. However, it is preferred to use plasma excitation means based on a plane antenna member, from a viewpoint such that the damage due to plasma can be reduced as little as possible, and a uniform oxide film can be formed.

(Plane Antenna Member)

In the present invention, it is preferred that a high-density plasma having a low electron temperature is generated by the irradiation of microwave via a plane antenna member having a plurality of slits, and an oxide film is formed on the surface of the above electronic device substrate by using the thus generated plasma. Such an embodiment enables a process, which accomplishes a light plasma damage, and a high reactivity at a low temperature.

For example, a paper (Ultra Clean Technology, Vol. 1.0 Supplement 1, p. 32, 1998, published by Ultra Clean Society) may be referred to, with respect to the details of microwave plasma apparatus which has such a plane antenna having many slits and is capable of generating plasma having a low electron temperature, providing a light plasma damage, and a high plasma density.

When the above new plasma apparatus is used, it can easily provide a plasma having an electron temperature of 1.5 eV or less, and plasma sheath voltage of several volts or less. Accordingly, in this case, the plasma damage can remarkably be reduced, as compared with that based on the conventional plasma (plasma sheath voltage of about 50 V). A new plasma apparatus comprising this plane antenna is capable of providing high-density radicals even at a temperature of room temperature to about 700° C., it is considered that it can suppress the deterioration of device characteristics due to heating, and it can provide a process having a high reactivity even at a low temperature.

(Preferred Plasma)

The characteristics of the plasma which may preferably be used in the present invention are as follows.

Electron temperature: 1.0 eV or less at a position immediately above the substrate;

Plasma density: 1×10¹² (1/cm³) or higher at a position immediately below the plane antenna;

Uniformity in plasma density: ±5% or less at a position immediately below the plane antenna.

As described the above, the process according to the present invention can form a high-quality oxide film having a small film thickness. Therefore, when another layer (for example, electrode layer) is to be formed on such an oxide film, a semiconductor device structure which is excellent in the characteristic may easily be formed.

In particular, the process according to the present invention can form a high-quality oxide film having an extremely thin film thickness (for example, film thickness of 2.5 nm or less). Accordingly, for-example, when poly-silicon or amorphous-silicon or SiGe is used as a gate electrode on this oxide film, an MOS-type semiconductor structure having a high performance can be formed.

(Preferred Characteristic of MOS Semiconductor Structure)

The extent or range to which the production process according to the present invention is applicable is not particularly limited. The extremely thin high-quality oxide film which can be formed by the present invention may particularly preferably be utilized as an insulator constituting a semiconductor device (particularly, gate insulator of an MOS semiconductor structure).

The present invention can easily produce an MOS semiconductor structure having a preferred characteristic as follows. When the characteristic of the oxide film which has been formed by the present invention is evaluated, for example, instead of the evaluation of the electric property of the above-mentioned oxide film per se, it is possible that a standard MOS semiconductor structure (e.g., a standard MOS semiconductor structure comprising (silicon/oxide film/polysilicon)) is formed, and the characteristic of the resultant MOS is evaluated. This is because, in such a standard MOS structure, the characteristic of the oxide film constituting the structure has a strong influence on the resultant MOS characteristic.

(One Embodiment of Production Process)

Hereinbelow, an embodiment of the production process according to the present invention is described.

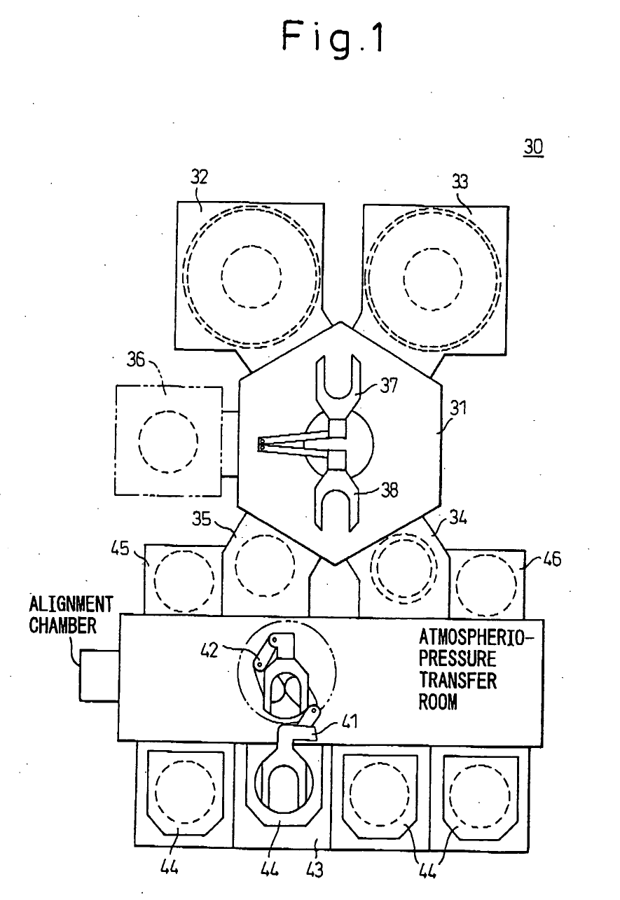

FIG. 1 is schematic view (schematic plan view) showing an example of the total arrangement of a semiconductor manufacturing equipment 30 for conducting the process for forming an oxide film according to the present invention.

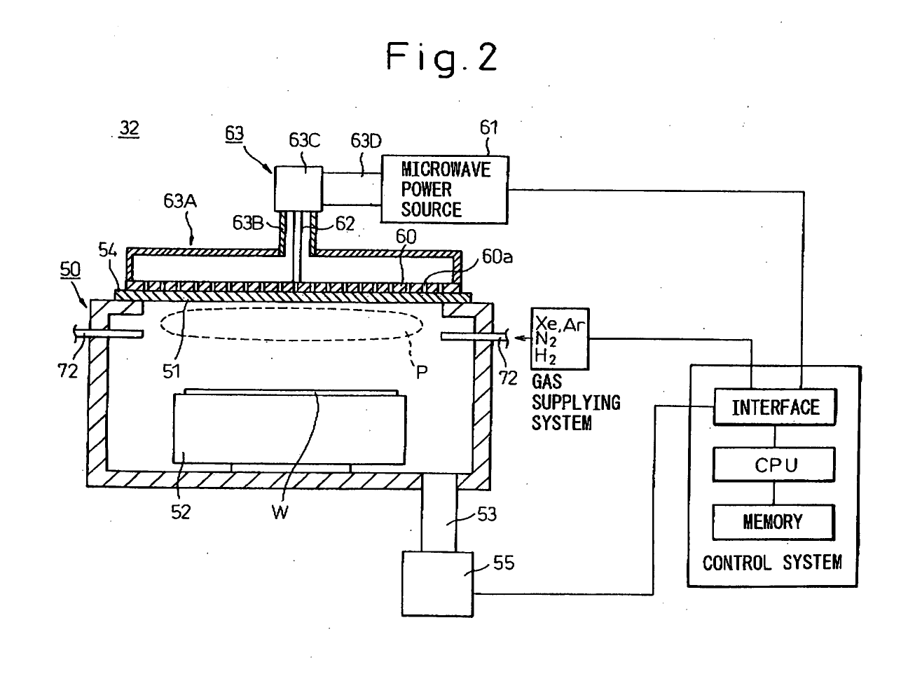

As shown in FIG. 1, in a substantially central portion of the semiconductor manufacturing equipment 30, there is disposed a transportation chamber 31 for transporting a wafer W (FIG. 2). Around the transportation chamber 31, there are disposed: plasma processing units 32 and 33 for conducting various treatments on the wafer, two load lock units 34 and 35 for conducting the communication/cutoff between the respective processing chambers, a heating unit 36 for operating various heating treatments, and a heating reaction furnace 47 for conducting various heating treatments on the wafer. These units are disposed so as to surround the transportation chamber 31. Alternatively, it is also possible to provide the heating reaction furnace 47 independently and separately from the semiconductor manufacturing equipment 30.

On the side of the load lock units 34 and 35, a preliminary cooling unit 45 and a cooling unit 46 for conducting various kinds of preliminary cooling and cooling treatments are disposed.

In the inside of transportation chamber 31, transportation arms 37 and 38 are disposed, so as to transport the wafer w (FIG. 2) between the above-mentioned respective units 32-36.

On the foreground side of the load lock units 34 and 35 in this FIG. 1, loader arms 41 and 42 are disposed. These loader arms 41 and 42 can put wafer W in and out with respect to four cassettes 44 which are set on the cassette stage 43, which is disposed on the foreground side of the loader arms 41 and 42.

In FIG. 1, as the plasma processing units 32 and 33, two plasma processing units of the same type are disposed in parallel.

Further, it is possible to exchange both of the plasma processing units 32 and 33 with a single-chamber type plasma processing unit. It is possible to set one or two of such a single-chamber type plasma processing unit in the position of plasma processing units 32 and 33.

When two plasma processing units 32 and 33 are used, it is possible that an SiO₂ film is formed in the plasma processing unit 32, and the SiO₂ film is surface-nitrided in the plasma processing unit 33. Alternatively, it is also possible that the formation of an SiO₂ film and the surface-nitriding of the SiO₂ film are conducted in parallel, in the plasma processing units 32 and 33. Further, it is also possible that an SiO₂ film is formed in another apparatus, and the SiO₂ film is surface-nitrided in parallel, in the plasma processing units 32 and 33.

In the embodiment shown in FIG. 1, it is also possible to dispose an alignment chamber adjacent to the atmospheric-pressure transfer room.

In FIG. 1, the load lock units 34 and 35 may have a cooling function, and in this case, cooling units 45 and 46 are omissible.

In FIG. 1, another plasma processing unit 32 for the SiO₂ film formation may be disposed instead of the plasma processing unit 33 for the surface nitridation. In this case, it is also possible to dispose a further plasma processing unit 32 adjacent to the transportation chamber 31 (i.e., three plasma processing unit 32 may be disposed).

As desired, at least one of the respective units, parts and/or components of the semiconductor manufacturing equipment 30 as shown in FIG. 1 may be controlled by using a control system (not shown) in the same manner as in the embodiment shown in FIG. 2 appearing hereinafter.

(One Embodiment of Film Formation of Gate Insulator)

FIG. 2 is a schematic sectional view in the vertical direction showing a plasma processing unit 32 (or 33) which is usable in the film formation of the gate insulator 2.

Referring to FIG. 2, reference numeral 50 denotes a vacuum container made of, e.g., aluminum. In the upper portion of the vacuum container 50, an opening portion 51 is formed so that the opening portion 51 is larger than a substrate (for example, wafer W). A top plate 54 in a flat cylindrical shape made of a dielectric such as quartz and aluminum nitride so as to cover the opening portion 51. In the side wall of the upper portion of vacuum container 50 which is below the top plate 54, gas feed pipes 72 are disposed in the 16 positions, which are arranged along the circumferential direction so as to provide equal intervals therebetween. A process gas comprising at least one kind of gas selected from O₂, inert gases, N₂, H₂, etc., can be supplied into the plasma region P in the vacuum container 50 from the gas feed pipes 72 evenly and uniformly.

On the outside of the top plate 54, there is provided a radio-frequency power source, via a slot plane antenna member 60 having a plurality of slits, which comprises a slot plane antenna (SPA) made from a copper plate, for example. As the radio-frequency power source, a waveguide 63 is disposed on the top plate 54, and the waveguide 63 is connected to a microwave power supply 61 for generating microwave of 2.45 GHz, for example. The waveguide 63 comprises a combination of: a flat circular waveguide 63A, of which lower end is connected to the SPA 60; a circular waveguide 63B, one end of which is connected to the upper surface side of the circular waveguide 63A; a coaxial waveguide converter 63C connected to the upper surface side of the circular waveguide 63B; and a rectangular waveguide 63D, one end of which is connected to the side surface of the coaxial waveguide converter 63C so as to provide a right angle therebetween, and the other end of which is connected to the microwave power supply 61.

In the present invention, a frequency region including UHF and microwave is referred to as radio-frequency (or high-frequency) region. The radio-frequency power supplied from the radio-frequency power source may preferably have a frequency of not smaller than 300 MHz and not larger than 2500 MHz, which may include UHF having a frequency of not smaller than 300 MHz and microwave having a frequency of not smaller than 1 GHz. In the present invention, the plasma generated by the radio-frequency power is referred to as “radio-frequency plasma”.

In the inside of the above-mentioned circular waveguide 63B, an axial portion 62 of an electroconductive material is coaxially provided, so that one end of the axial portion 62 is connected to the central (or nearly central) portion of the SPA 60 upper surface, and the other end of the axial portion 62 is connected to the upper surface of the circular waveguide 63B, whereby the circular waveguide 63B constitutes a coaxial structure. As a result, the circular waveguide 63B is constituted so as to function as a coaxial waveguide.

In addition, in the vacuum container 50, a stage 52 for carrying the wafer W is provided so that the stage 52 is disposed opposite to the top plate 54. The stage 52 contains a temperature control unit (not shown) disposed therein, so that the stage can function as a hot plate. Further, one end of an exhaust pipe 53 is connected to the bottom portion of the vacuum container 50, and the other end of the exhaust pipe 53 is connected to a vacuum pump 55.

As shown in FIG. 2, in this embodiment, the gas supplying system, the microwave power source 61 and the vacuum pump 55 are connected to a control system. The control system comprises, at least, an interface, a CPU and a memory so as to control the functions and performances of the gas supplying system, the microwave power source 61 and the vacuum pump 55.

(One Embodiment of Slot Plane Antenna)

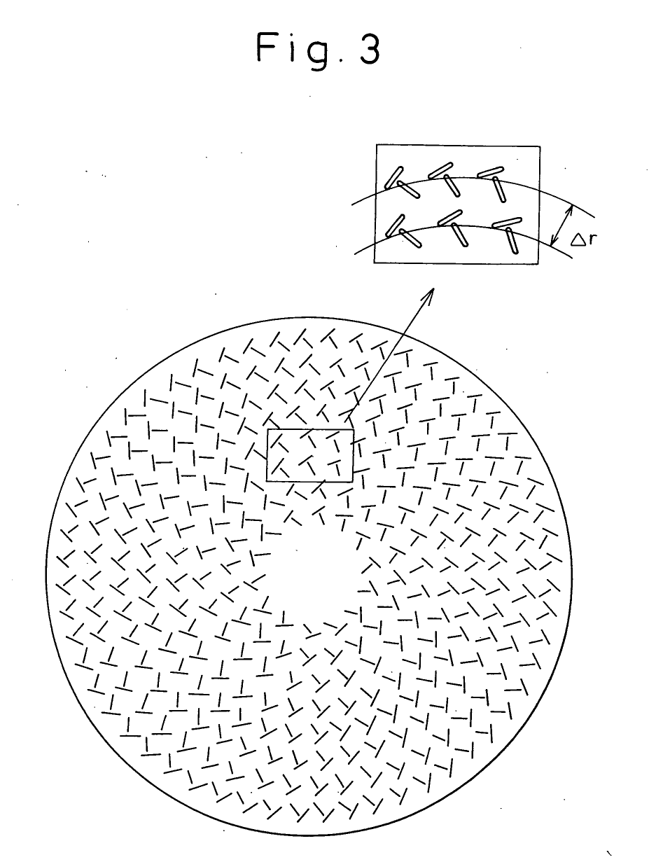

FIG. 3 is a schematic plan view showing an example of slot plane antenna 60 which is usable in an apparatus for producing an electronic device material according to the present invention.

As shown in this FIG. 3, on the surface of the slot plane antenna 60, a plurality of slots 60a, 60a, . . . are provided in the form of concentric circles. Each slot 60a is a substantially square penetration-type groove. The adjacent slots are disposed perpendicularly to each other and arranged so as to form a shape of alphabetical “T”-type character. The length and the interval of the slot 60a arrangement are determined in accordance with the wavelength of the microwave supplied from the microwave power supply unit 61.

(One Embodiment of Heating Reaction Furnace)

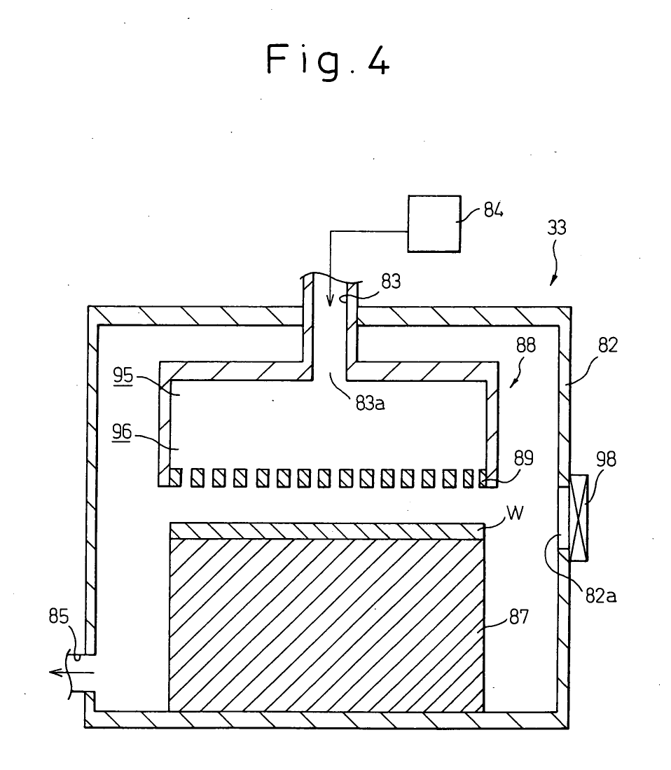

FIG. 4 is schematic sectional view in the vertical direction showing an example of the heating reaction furnace 47 which is usable in an apparatus for producing an electronic device material according to the present invention.

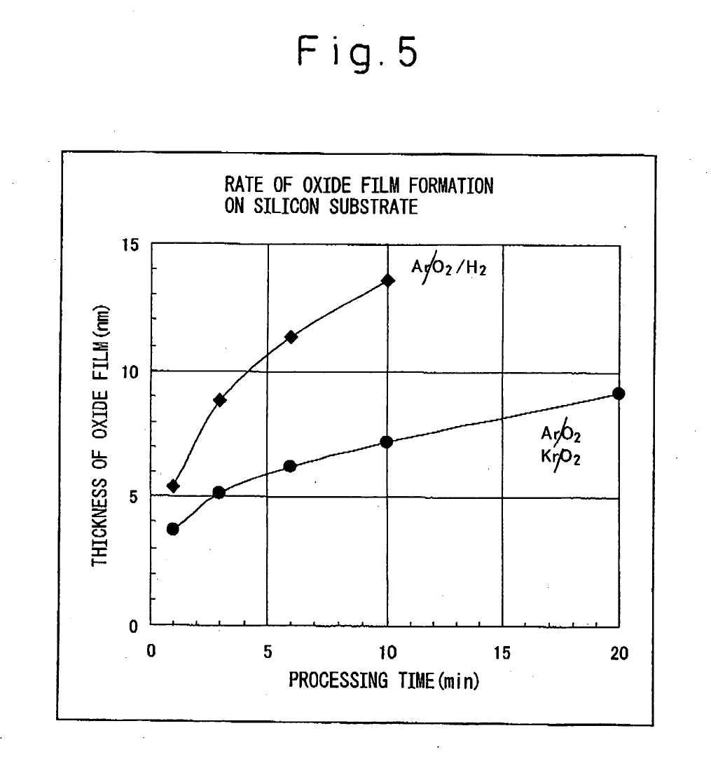

As shown in FIG. 4, a processing chamber 82 of the heating reaction furnace 47 chamber is formed into an air-tight structure by using aluminum, for example. A heating mechanism and a cooling mechanism are provided in the processing chamber 82, although these mechanisms are not shown in FIG. 5.

As shown in FIG. 4, a gas introduction pipe 83 for introducing a gas into the processing chamber 82 is connected to the upper central portion of the processing chamber 82, the inside of the processing chamber 82 communicates with the inside of the gas introduction pipe 83. In addition, the gas introduction pipe 83 is connected to a gas supply source 84. A gas is supplied from the gas supply source 84 into the gas introduction pipe 83, and the gas is introduced into the processing chamber 82 through the gas introduction pipe 83. As the gas in this case, it is possible to use one of various gases such as raw material for forming a gate electrode (electrode-forming gas) such as silane, for example. As desired, it is also possible to use an inert gas as a carrier gas.

A gas exhaust pipe 85 for exhausting the gas in the processing chamber 82 is connected to the lower portion of the processing chamber 82, and the gas exhaust pipe 85 is connected to exhaust means (not shown) such as vacuum pump. On the basis of the exhaust means, the gas in the processing chamber 82 is exhausted through the gas exhaust pipe 85, and the processing chamber 82 is maintained at a desired pressure.

In addition, a stage 87 for carrying wafer W is provided in the lower portion of the processing chamber 82.

In the embodiment as shown in FIG. 4, the wafer W is carried on the stage 87 by means of an electrostatic chuck (not shown) having a diameter which is substantially the same as that of the wafer W. The stage 87 contains a heat source means (not shown) disposed therein, to thereby constitute a structure wherein the surface of the wafer W to be processed which is carried on the stage 87 can be adjusted to a desired temperature.

The stage 87 has a mechanism which is capable of rotating the wafer W which carried the stage 87, as desired.

In FIG. 4, an opening portion 82a for putting the wafer w in and out with respect to the processing chamber 82 is provided on the surface of the right side of the processing chamber 82 in this figure. The opening portion 82a can be opened and closed by moving a gate valve 98 vertically (up and down direction) in this figure. In FIG. 4, a transportation arm (not shown) for transporting the wafer is provided adjacent to the right side of the gate valve 98. In. FIG. 4, the wafer W can be carried on the stage 87, and the wafer W after the processing thereof is transported from the processing chamber 82, as the transportation arm enters the processing chamber 82 and goes out therefrom through the medium of the opening portion 82a.

Above the stage 87, a shower head 88 as a shower member is provided. The shower head 88 is constituted so as to define the space between the stage 87 and the gas introduction pipe 83, and the shower head 88 is formed from aluminum, for example.

The shower head 88 is formed so that the gas exit 83a of the gas introduction pipe 83 is positioned at the upper central portion of the shower head 88. The gas is introduced into the processing chamber 82 through gas feeding holes 89 provided in the lower portion of the shower head 88.

(Embodiment of Oxide Film Formation)

Next, there is described a preferred embodiment of the process wherein an insulating film comprising a gate insulator 2 is formed on a wafer W (such as silicon substrate) by using the above-mentioned apparatus.

Referring to FIG. 1, a gate valve (not shown) provided at the side wall of the vacuum container 50 in the plasma processing unit 32 (FIG. 1) is opened, and the above-mentioned wafer W comprising the silicon substrate 1 is placed on the stage 52 (FIG. 2) by means of transportation arms 37 and 38.

Next, the gate valve was closed so as to seal the inside of the vacuum container 50, and then the inner atmosphere therein is exhausted by the vacuum pump 55 through the exhaust pipe 53 so as to evacuate the vacuum container 50 to a predetermined degree of vacuum and a predetermined pressure in the container 50 is maintained. On the other hand, microwave (e.g., of 1.80 GHz and 2200 W) is generated by the microwave power supply 61, and the microwave is guided by the waveguide so that the microwave is introduced into the vacuum container 50 via the SPA 60 and the top plate 54, whereby radio-frequency plasma is generated in the plasma region P of an upper portion in the vacuum container 50.

Herein, the microwave is transmitted in the rectangular waveguide 63D in a rectangular mode, and is converted from the rectangular mode into a circular mode by the coaxial waveguide converter 63C. The microwave is then transmitted in the cylindrical coaxial waveguide 63B in the circular mode, and transmitted in the circular waveguide 63A in the expanded state, and is emitted from the slots 60a of the SPA 60, and penetrates the plate 54 and is introduced into the vacuum container 50. In this case, microwave is used, and accordingly high-density plasma can be generated. Further, the microwave is emitted from a large number of slots 60a of the SPA 60, and accordingly the plasma is caused to have a high plasma density.

Subsequently, while the wafer W is heated to 400° C., for example, by regulating the temperature of the stage 52, the first step (formation of an oxide film) is conducted by introducing via the gas feed pipe 72 a process gas for an oxide film formation comprising an inert gas such as krypton and argon, O₂ gas, and H₂ gas at flow rates of 500 sccm, 5 sccm and 5 sccm, respectively.

In this process, the introduced process gas is activated (converted into plasma) by plasma flux which has been generated in the plasma processing unit 32, and on the basis of the thus generated plasma, the surface of the wafer w is oxidized, to thereby form an oxide film (SiO₂ film) 2.

Next, the gate valve (not shown) is opened, and the transportation arms 37 and 38 (FIG. 1) are caused to enter the vacuum container 50, so as to receive the wafer W on the stage 52. The transportation arms 37 and 38 take out the wafer W from the plasma processing unit 32, and then set the wafer W in the stage in the adjacent plasma processing unit 33.

In addition, the present invention provides a program which causes a computer to function as a controller for conducting the above-mentioned process for forming an oxide film, and is capable of running in association with a computer.

The present invention also provides a program which causes a computer to conduct at least one step of the above-mentioned process for forming an oxide film, and is capable of running in association with a computer.

The present invention further provides a computer-readable medium, which stores a program which causes a computer to function as a controller for conducting the above-mentioned process for forming an oxide film, or a program which causes a computer to conduct at least one step of the above-mentioned process for forming an oxide film. The program which has been read from the computer-readable medium can perform the above-mentioned function in association with a computer.

Further, the constitution of the present invention may be accomplished by using a hardware or a software, or an appropriate combination of a hardware or a software.

### EXAMPLES

Hereinbelow, the present invention will be described in more detail with reference to Examples.

### Example 1

(Oxide Film Formation)

An oxide film was formed on a silicon substrate at a high speed, by using a process for forming an oxide film according to the present invention. In this oxide film formation, there was used an SPA-type plasma chamber as shown in FIGS. 1-4.

As a silicon substrate, there was used a single-crystal silicon substrate (wafer) having a resistivity of 3 Ω·cm, a diameter of 200 mm, F-type, and a plane direction (100).

(Washing)

The silicon substrate was cleaned in accordance with a procedure including the following steps (1) to (6).
(1) Immersion in a mixture of an aqueous ammonia solution and hydrogen peroxide solution for 10 minutes;
(2) Rinsing with pure water;
(3) Immersion in a mixture of aqueous hydrochloric acid solution and hydrogen peroxide solution for 10 minutes;
(4) Rinsing with pure water;
(5) Immersion in a dilute aqueous hydrofluoric acid solution for 3 minutes; and
(6) Rinsing with pure water.

A natural oxidation film which had been present on the surface of the silicon substrate was removed by the cleaning with the dilute aqueous HF solution in the above step (5), and the silicon surface was terminated with hydrogen atoms. An oxide film was formed on the thus cleaned silicon substrate surface, by using a slot plane antenna-type plasma chamber in the following manner. The time period between the completion of the pure water rinsing in the above step (6) and the setting of the cleaned silicon substrate in the slot plane antenna-type plasma chamber was about 15 minutes.

(Oxide Film Formation)

The silicon substrate after the above cleaning step was placed on the substrate stage (400° C.) in the slot plane antenna-type plasma chamber of FIG. 2, and was irradiated with plasma under the following conditions while flowing thereinto an inert gas (Ar), an oxygen gas and a hydrogen gas under-the following conditions. Herein, the distance between things of the silicon substrate and the slot plane antenna-type plasma antenna was 60 cm.

<Gas Supply Conditions>

Inert gas (Ar): 500 sccm

Oxygen gas (O₂): 5 sccm

Hydrogen gas (H₂): 5 sccm

Pressure in chamber: 133.3 Pa

Temperature of substrate to be processed: 400° C.

<Plasma Irradiation Conditions>

Microwave power: 3.5 kw

### Comparative Example 1

Each of the two kinds of oxide films was formed in the same manner as in Example 1 on a silicon substrate which was the same as that used in Example 1, except for changing the gas supply conditions in the following manner.

<Gas Supply Conditions-1>

Inert gas (Ar): 500 sccm

Oxygen gas (O₂): 5 sccm

<Gas Supply Conditions-2>

Inert gas (Kr): 500 sccm

Oxygen gas (O₂): 5 sccm

### Example 2

(Measurement of Oxide Film Thickness)

The oxidizing rates for the silicon substrate obtained in Example 1 and Comparative Example were determined from the oxidation time and the thickness of the formed oxide film. The oxide film thickness was measured by using an optical thickness meter (ellipsometry method), or on the basis of the observation of the cross-section of the substrate using a microscope.

The results of the above measurement by the optical thickness meter (ellipsometry method) are shown in the graph of FIG. 4. As shown in this graph, the rate of the oxide film formation obtained in Example 1 was about twice that obtained in Comparative Example (gas supply conditions-1 and gas supply conditions-2).

### Example 3

(Confirmation of Chemical Characteristic)

The chemical resistance of the silicon oxide film to HF (hydrofluoric acid) as a representative etching agent was measured.

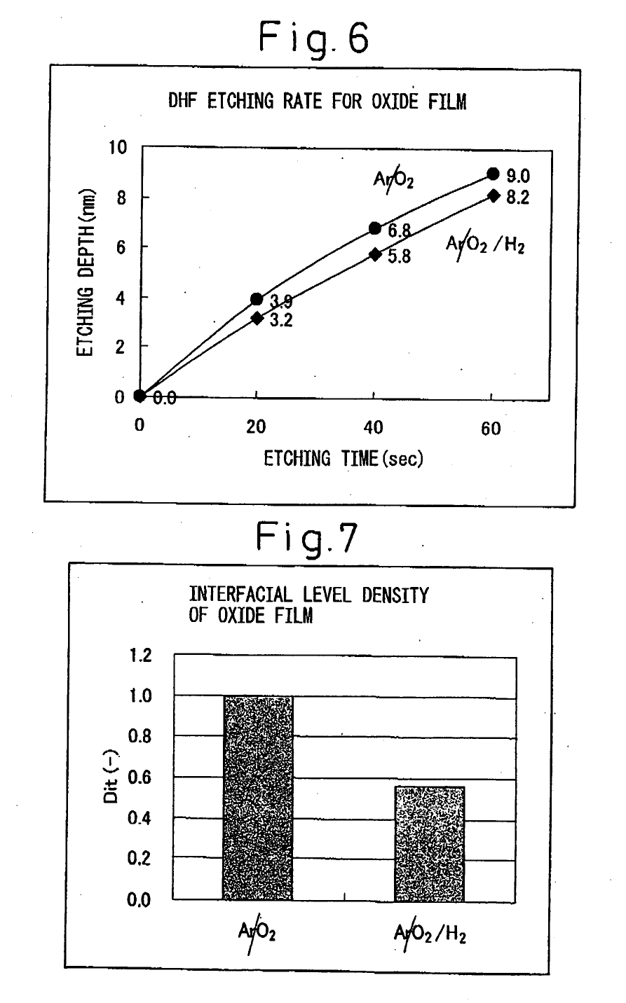

Each of the silicon substrates having the oxide film which had been formed in Example 1, Comparative Example 1, etc., was left standing while being immersed in a 1%-HF aqueous solution, at 23° C. for a predetermined time period. The thus obtained resultant film thickness-after the immersion was compared with the film thickness which had been measured in the same manner before the immersion. The result of the above measurement are shown in the graph of FIG. 6. As shown in this graph, the chemical resistance of the oxide film obtained in Example 1 was improved as compared with that of the oxide film which had been formed under the conditions of plasma inert gas+oxygen gas in Comparative Example.

### Example 4

(Confirmation of Interfacial Characteristic)

The interfacial level density of the Si/SiO interface under the following conditions by using a non-contact charge monitor measuring apparatus for gate oxide film (trade name: Quantox, mfd. by KLA Tencor Co.).

The results of the above measurement are shown in the graph of FIG. 7. As shown in this graph, the interfacial level density of the oxide film obtained in Example 1 was improved so as to provide an about half value, as compared with that or the oxide film which had been formed in Comparative Example 1 under the conditions of plasma inert gas+oxygen gas.

### Example 5

(Confirmation of Chemical Bonding State)

The chemical compositions were evaluated by using an XPS (X-ray photoelectron spectroscopy; an X-ray source: Mg-Ka, 10 kV, 30 mA) with respect to the oxide film having a film thickness of 10 nm which had been obtained in Example 1 (i.e., oxide film which had been formed by the addition of hydrogen) and the conventional oxide film.

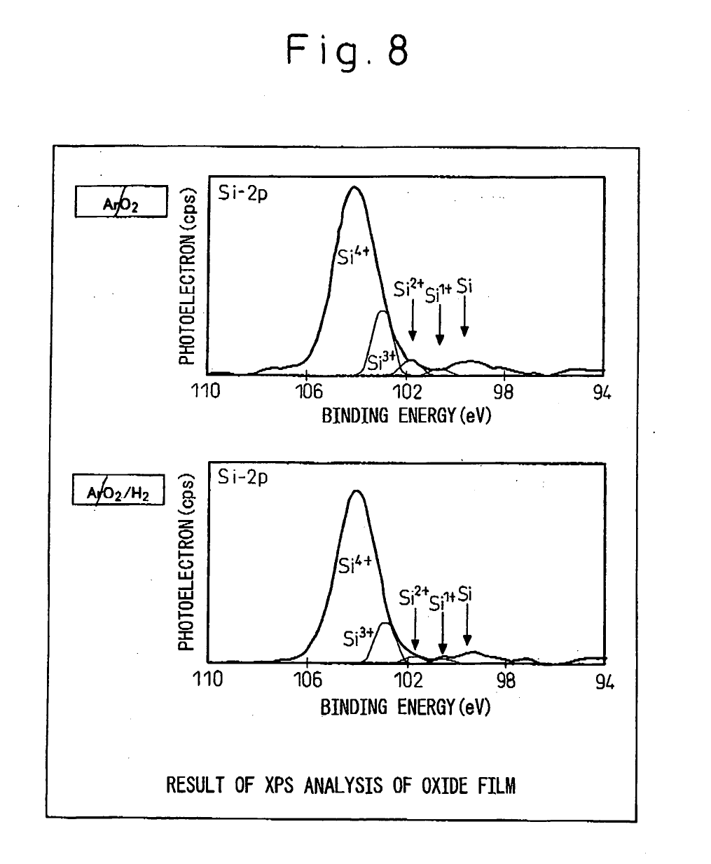

The results of the above measurement are shown in the graphs of FIG. 8(a) and FIG. 8(b). As shown in the graph of FIG. 8(a), the oxide film obtained in Example 1 had a smaller quantity of unstable Si—O bondings which can be observed between the Si—O and Si—Si bonding peaks. Accordingly, it was found that the oxide film obtained in Example 1 had a good quality.

### Example 6

(Measurement of Oxide Film Surface Roughness)

The surface roughnesses of the oxide films were measured by using an AFM (atomic force microscope), with respect to the oxide film having a film thickness of 10 nm which had been obtained in Example 1 (i.e., oxide film which had been formed by the addition of hydrogen) and the conventional oxide film.

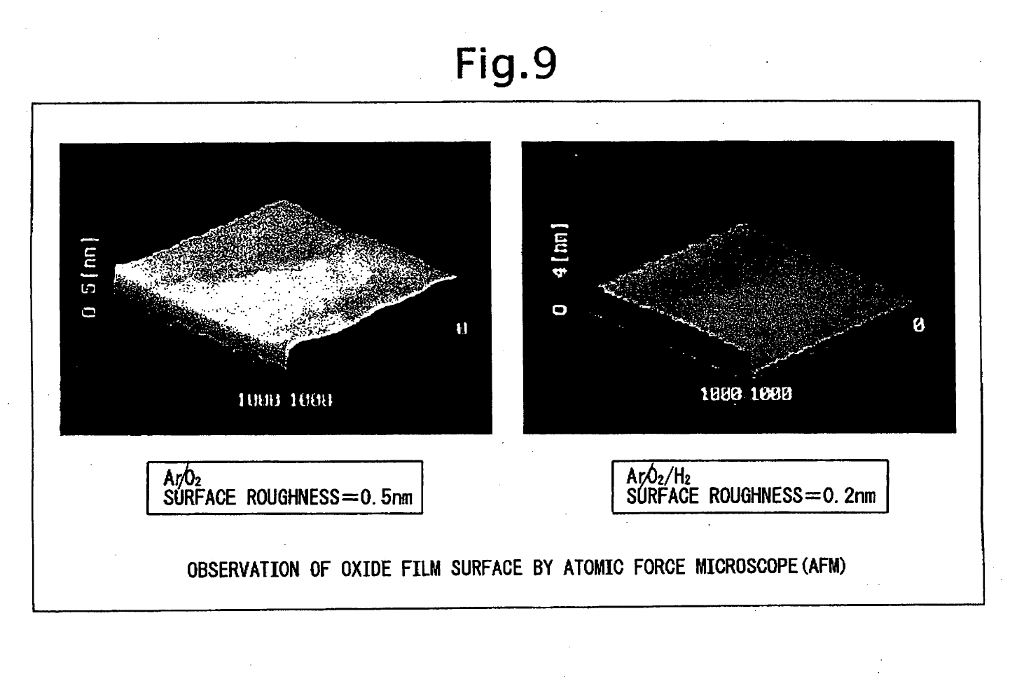

The results of the above measurement are shown in the data of FIG. 9(a) and FIG. 9(b). As shown in the data of FIG. 9(a), the oxide film obtained in Example 1 had a larger smoothness (i.e., had a smaller surface roughness), as compared with that of the oxide film which had been formed (under the conditions of plasma inert gas+oxygen gas) in Comparative Example 1 as shown in the data of FIG. 9(b). Accordingly, it was found that the oxide film obtained in Example 1 was more suitable as an underlying oxide film to be subjected to a subsequent processing step.

### Example 7

(Measurement of Refractive Index and Relative Density of Oxide Film)

The refractive index and relative density were evaluated with respect to the oxide film having a film thickness of 10 nm which had been obtained in Example 1 (i.e., oxide film which had been formed by the addition of hydrogen) and the conventional oxide film.

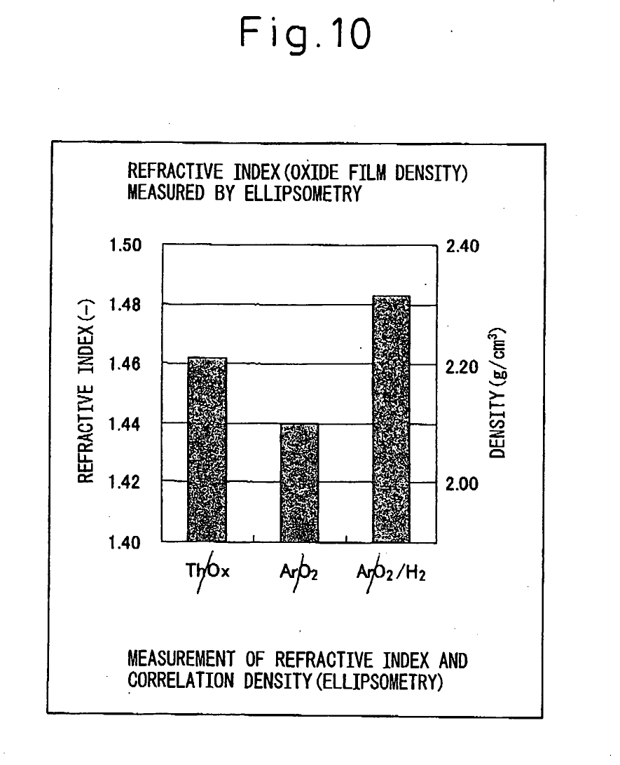

The thus obtained data are shown in FIG. 10.

From these data, it was found that the oxide film obtained in Example 1 had a higher refractive index and a higher density than that of the oxide film obtained Comparative Example 1.

In addition, it was also found that the oxide film obtained in Example 1 had a higher density than that of a thermal oxidation film.

### Example 8

(Measurement of Oxide Film Density)

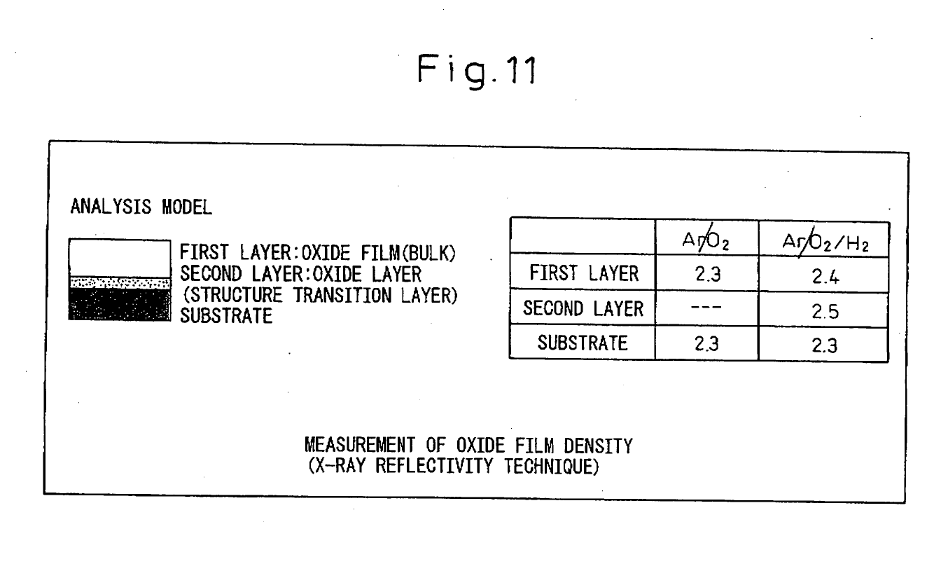

The results of the density measurement using an X-ray reflectivity method, as a verification of Example 7 are shown in FIG. 11.

The measurement was conducted by using GIXR technique, and the data were analyzed by using a two-layer structure as a typical model for an oxide film which has been provided by oxidizing a silicon substrate.

The data provided by the above measurement are shown in FIG. 11.

It was found that the oxide film obtained in Example 1 showed a two-layer structure, and had a higher density than that of the oxide film obtained in Comparative Example 1.

### Example 9

(Evaluation of Electric Characteristics of Oxide Film)

An MOS semiconductor structure was fabricated by using the oxide film obtained in Example 1, and the electric characteristics thereof were evaluated.

This evaluation was conducted in accordance with a technique which has generally been used for the purpose of evaluating the reliability of an oxide film. More specifically, in this evaluation, the quantities of electric charges passing through the oxide film to be evaluated were measured and compared with each other, when a constant electrical current was flown through the oxide film until the oxide film was destroyed. The substrate used herein was a P-type silicon having a diameter of 200 mmφ. The MOS structure was obtained by forming an oxide film on the substrate, and then depositing polysilicon on the oxide film as an electrode.

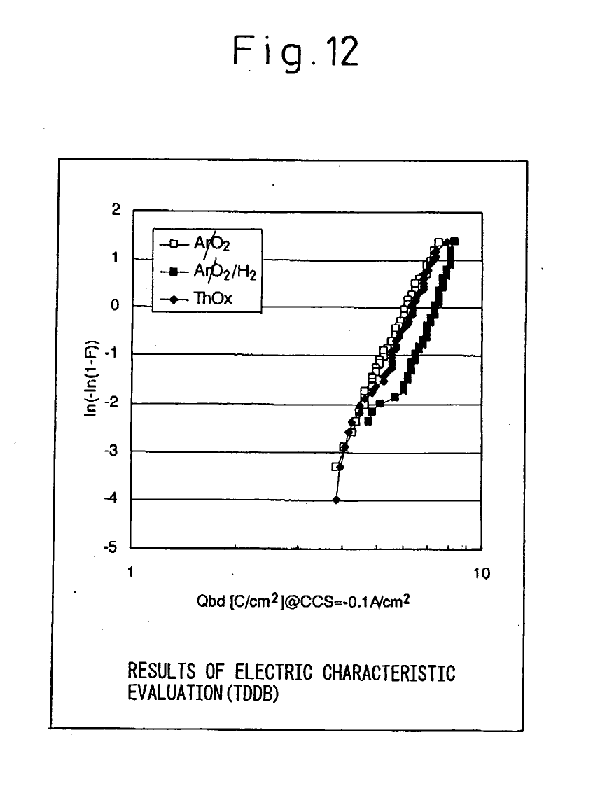

The data obtained in the above measurement are shown in FIG. 12.

It was found that the oxide film obtained in Example 1 showed a larger quantity of electric charges passing through the oxide film until the destruction of the oxide film, as compared with those in the case of the oxide film obtained in Comparative Example 1, and thermal oxidation film. Accordingly, it was found that the oxide film obtained in Example 1 had a better reliability.

Those skilled in the art will appreciate that all or part of systems and methods consistent with the present invention may be stored on or read from other computer-readable media, such as secondary storage devices, like hard disks, floppy disks, and CD-ROM; a carrier wave received from the Internet; or other forms of computer-readable memory, such as read-only memory (ROM) or random-access memory (RAM).

One skilled in the art will appreciate that a system suitable for use with the exemplary embodiments may be implemented with additional or different components (such as multiple processors, routers or subnetworks, multiple computers or computing devices in communication with each other) and a variety of input/output devices and program modules (such as interactive TV set-top receivers with EEPROM memories containing their operating instructions).

Furthermore, one skilled in the art will also realize that an appropriate program module (e.g. one suitable for the control system as shown in FIG. 2) may be implemented in a variety of ways and include multiple other modules, programs, applications, scripts, processes, threads, or code sections that all functionally interrelate with each other to accomplish the individual tasks described above for each module, script, and daemon. For example, it is contemplated that these programs modules may be implemented using commercially available software tools, using custom object-oriented code written in the C++ programming language, using applets written in the Java programming language, or may be implemented as with discrete electrical components or as one or more hardwired application specific integrated circuits (ASIC) custom designed just for this purpose.

In the above-described embodiments, microwave plasma has been used. However, in the present invention, it is also usable various plasmas such as inductively-coupled plasma, reflected-wave plasma, and ECR plasma.

Industrial Applicability

As described hereinabove, the present invention provides a process for forming an oxide film and an apparatus for forming oxide film which can provide a high-quality oxide film and can easily control the thickness of the oxide film, and a material for electronic device having such a high-quality oxide film.

In the present invention, an embodiment wherein an oxide film is formed at a low temperature (500° C. or below), is particularly advantageous in a case using a large-diameter (300 mm) substrate for electronic devices (which is extremely-difficult to be uniformly heated or cooled, as compared in the case of a conventional small-diameter (200 mm) substrate). More specifically, when the substrate is processed at a low temperature, it is possible to easily suppress the occurrence of defects as little as possible, although these defects could be caused when such a large-diameter substrate (or wafer) is used in the prior art.

1. A process for forming an oxide film, wherein in the presence of a process gas comprising at least an oxygen gas and a hydrogen gas, the surface of a substrate for electronic device is irradiated with plasma based on oxygen and hydrogen, to thereby form an oxide film on the substrate for electronic device.

2. A process for forming an oxide film according to claim 1, wherein the substrate for electronic device is a substrate for liquid crystal device, or comprises silicon as a main component.

3. A process for forming an oxide film according to claim 1, wherein the plasma is based on a slot plane antenna.

4. A process for forming an oxide film according to claim 1, wherein the ratio (0₂:H₂) between the oxygen gas and hydrogen gas in the process gas is 1:2-2:1.

5. A process for forming an oxide film according to claim 1, wherein the oxide film is formed at a temperature of room temperature to 500° C.

6. A process for forming an oxide film according to claim 1, wherein the oxide film is formed at a pressure of 66.7-266.6 Pa.

7. A process for forming an oxide film according to claim 1, wherein the plasma is based on oxygen, hydrogen and an inert gas.

8. A process for forming an oxide film according to claim 7, wherein the inert gas is Ar, Kr or He.

9. A process for forming an oxide film according to claim 8, wherein the flow rate ratio (02:H2:inert gas) in the process gas is 0.5:0.5:100 to 2:2:100.

10. A process for forming an oxide film according to claim 1, wherein the plasma electron temperature is 1.5 eV or less.

11. A process for forming an oxide film according to claim 1, wherein the plasma electron temperature immediately above the substrate is 1.0 ev or less.

12. A process for forming an oxide film, comprising:
cleaning a substrate with a dilute hydrofluoric acid solution,
introducing the substrate into a plasma chamber,
introducing a process gas comprising an inert gas, oxygen and hydrogen into the plasma chamber, generating plasma in the plasma chamber so as to irradiate the substrate with the plasma, to thereby form an oxide film on the substrate.

13. A process for forming an oxide film according to claim 12, wherein the substrate is a substrate for liquid crystal device, or comprises silicon as a main component.

14. A process for forming an oxide film according to claim 12, wherein the plasma is based on a slot plane antenna.

15. A process for forming an oxide film according to claim 12, wherein the ratio (O₂:H₂) between the oxygen gas and hydrogen gas in the process gas is 1:2 to 2:1.

16. A process for forming an oxide film according to claim 12, wherein the oxide film is formed at a temperature of room temperature to 500° C.

17. A process for forming an oxide film according to claim 12, wherein the oxide film is formed at a pressure of 66.7-266.6 Pa.

18. A process for forming an oxide film according to claim 12, wherein the plasma is based on oxygen, hydrogen and an inert gas.

19. A process for forming an oxide film according to claim 18, wherein the inert gas is Ar, Kr or He.

20. A process for forming an oxide film according to claim 19, wherein the flow rate ratio (0₂:H₂:inert gas) in the process gas is 0.5:0.5:100 to 2:2:100.

21. A process for forming an oxide film according to claim 12, wherein the plasma electron temperature is 1.5 eV or less.

22. A process for forming an oxide film according to claim 12, wherein the plasma electron temperature immediately above the substrate is 1.0 eV or less.

23. A material for electronic device, comprising: a substrate for electronic device; and an oxide film covering at least a portion of a surface of the electronic device substrate; wherein the ratio (Rp/Rs) between the surface roughness (Rs) of the electronic device substrate before the formation of the oxide film, and the surface roughness (Rp) of the oxide film which has been formed on the electronic device substrate is 2 or less.

24. A material for electronic device according to claim 23, wherein the substrate for electronic device comprises silicon as a main component.

25. A program for causing a computer to function as a controller for conducting a process for forming an oxide film according to claim 1.

26. A program for causing a computer to conduct at least one step of a process for forming an oxide film according to claim 1.

27. A computer-readable medium, which stores a program according to claim 25.

28. A computer-readable medium, which stores a program according to claim 26.
